(19) United States
(12) Patent Application Publication
(10) Pub. No.: US 2020/0350892 A1
(43) Pub. Date: Nov. 5, 2020

(54) FRONT END MODULE

(71) Applicant: Samsung Electro-Mechanics Co., Ltd., Suwon-si (KR)

(72) Inventor: Myeong Han YU, Suwon-si (KR)

(73) Assignee: Samsung Electro-Mechanics Co., Ltd., Suwon-si (KR)

(21) Appl. No.: 16/541,411

(22) Filed: Aug. 15, 2019

(30) Foreign Application Priority Data
Apr. 30, 2019 (KR) 10-2019-0050540

(51) Int. Cl. H03H 9/60; H03H 9/58; H03H 3/02; H04B 1/00

(52) U.S. Cl. CPC H03H 9/605; H04B 1/0057; H03H 3/02; H03H 9/582

(57) ABSTRACT

A front end module includes: a first filter configured to operate as a bandpass filter, and to support communications in a 4.4 GHz to 5.0 GHz band; and a second filter configured to operate as a high-pass filter, and to support communications in a 5.15 GHz to 5.835 GHz band.

### CROSS-REFERENCE TO RELATED APPLICATIONS

This application claims the benefit under 35 U.S.C. § 119(a) of Korean Patent Application No. 10-2019-0050540 filed on Apr. 30, 2019 in the Korean Intellectual Property Office, the entire disclosure of which is incorporated herein by reference for all purposes.

### BACKGROUND

### 1. Field

The following description relates to a front end module.

### 2. Description of Related Art

5G mobile communications have been developed to use a frequency band between 28 and 29 GHz, a millimeter wave (mmWave), and a frequency band of 5 GHz, which is a sub-6 GHz band.

In 5G mobile communications, as a width between adjacent frequency bands is reduced, it is necessary to reduce interference between adjacent bands by using a bulk acoustic wave (BAW) filter having excellent attenuation characteristics. However, a BAW filter having a bandpass characteristic has excellent attenuation characteristics between the adjacent bands because a frequency interval between a resonance frequency and an anti-resonance frequency is as narrow as about 200 MHz. However, since it is difficult to form a passband wider than 600 MHz, it may be difficult to apply such a BAW filter to 5G communications in which broadband frequency characteristics are required.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a front end module includes: a first filter configured to operate as a bandpass filter, and to support communications in a 4.4 GHz to 5.0 GHz band; and a second filter configured to operate as a high-pass filter, and to support communications in a 5.15 GHz to 5.835 GHz band.

The first filter and the second filter may each include at least one bulk acoustic resonator.

The first filter may have a lower limit frequency of 4.4 GHz and an upper limit frequency of 5.0 GHz.

The second filter may have a lower limit frequency of 5.15 GHz.

The second filter may be configured to support a radio frequency signal of 5.15 GHz or more.

The first filter may be configured to support cellular communications.

The second filter may be configured to support Wi-Fi communications.

The first filter and the second filter may be implemented as a single chip.

In another general aspect, a front end module includes: an antenna; a diplexer connected to the antenna; and a filter unit including a first filter connected to the diplexer and configured to support communications in a 4.4 GHz to 5.0 GHz band, and a second filter connected to the diplexer and configured to support communications in a 5.15 GHz to 5.835 GHz band. The first filter may be configured to operate as a bandpass filter and the second filter may be configured to operate as a high-pass filter.

The second filter may have a lower limit frequency of 5.15 GHz.

The second filter may be configured to cover a radio frequency signal of 5.15 GHz or more.

The filter unit may further include a third filter connected to the diplexer and configured to support communications in a 2.4 GHz to 2.4835 GHz band.

The first filter, the second filter, and the third filter may each include at least one bulk acoustic resonator.

The first filter, the second filter, and the third filter may be implemented as a single chip.

The first filter may be configured to support cellular communications. The second filter and the third filter may be configured to support Wi-Fi communications.

The first filter may be configured to support cellular communications.

Other features and aspects will be apparent from the following detailed description, the drawings, and the claims.

### BRIEF DESCRIPTION OF DRAWINGS

FIG. 1 is a cross-sectional view of a filter, according to an embodiment.

FIG. 2 is a circuit diagram of a filter including a bulk acoustic resonator, according to an embodiment.

FIG. 3 shows a frequency response of the filter of FIG. 2.

FIG. 4 is a block diagram of a front end module, according to an embodiment.

FIG. 5 is a simulation graph, according to an embodiment.

FIG. 6 is a block diagram of a front end module, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

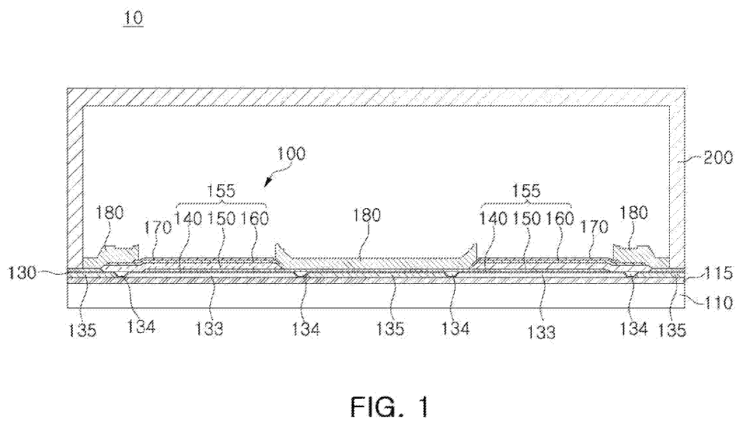

FIG. 1 is a cross-sectional view illustrating a filter 10, according to an embodiment.

Referring to FIG. 1, the filter 10 may include at least a bulk acoustic resonator 100 and a cap 200. In FIG. 1, the filter 10 is illustrated as including two bulk acoustic resonators 100, but according to other embodiments, the filter 10 may include one bulk acoustic resonator 100 or three or more bulk acoustic resonators 100. The bulk acoustic resonator 100 may be a thin film bulk acoustic resonator (FBAR).

The bulk acoustic resonator 100 may be constituted by a laminated structure composed of a plurality of films. The laminated structure constituting the bulk acoustic resonator 100 may include a substrate 110, an insulating layer 115, a cavity 133, a support member 134, an auxiliary support member 135, and a resonating unit 155 including a first electrode 140, a piezoelectric layer 150, and a second electrode 160. The laminated structure constituting the bulk acoustic resonator 100 may further include a protective layer 170 and a metal layer 180.

According to an example manufacturing process of the bulk acoustic resonator 100, a sacrificial layer may be formed on the insulating layer 115, and then a portion of the sacrificial layer may be removed to form a pattern. A width of an upper surface of the pattern may be wider than a width of a lower surface of the pattern, and a side surface of the pattern connecting the upper surface and the lower surface may be inclined. After forming the pattern on the sacrificial layer, a membrane 130 may be formed on portions of the insulating layer 115 that are exposed externally and the sacrificial layer. After forming the membrane 130, an etch stop material underlying formation of the support member 134 is formed to cover the membrane 130.

After forming the etch stop material, one surface of the etch stop material is planarized, such that a portion of the membrane 130 formed on the upper surface of the sacrificial layer is exposed externally. In a process of planarizing one surface of the etch stop material, a portion of the etch stop material may be removed, and then the support member 134 may be formed by a part of the etch stop material remaining in the pattern after the portion of the etch stop material is removed. As a result of the planarization process of the etch stop material, upper surfaces of the support member 134 and the sacrificial layer may be substantially flat. The membrane 130 may function as a stop layer of the planarization process of the etch stop material.

Thereafter, the cavity 133 may be formed by an etching process in which the sacrificial layer is etched and removed after the first electrode 140, the piezoelectric layer 150, and the second electrode 160, and other possible layers are laminated. For example, the sacrificial layer may include polycrystalline silicon (Poly-Si). The cavity 133 may be located in a lower portion of the resonating unit 155 such that the resonating unit 155 composed of the first electrode 140, the piezoelectric layer 150, and the second electrode 160 may vibrate in a predetermined direction.

The substrate 110 may be composed of a silicon substrate, and the insulating layer 115 may be provided to electrically isolate the resonating unit 155 for the substrate 110 on the upper surface of the substrate 110. The insulating layer 115 may be formed of any one or any combination of any two or more of silicon dioxide (SiO2), silicon nitride (Si3N4), aluminum oxide (Al2O2), and aluminum nitride (AlN), and may be formed on the substrate 110 by chemical vapor deposition, RF magnetron sputtering or evaporation.

The cavity 133 and the support member 134 may be formed on the insulating layer 115. As described above, the cavity 133 may be formed by an etching process in which the sacrificial layer is formed on the insulating layer 115 and a pattern provided with the support member 134 on the sacrificial layer is formed, and then the sacrificial layer is etched and removed after the first electrode 140, the piezoelectric layer 150, second electrode 160, and other possible layers are laminated.

The cavity 133 may be located in a lower portion of the resonating unit 155 such that the resonating unit 155 composed of the first electrode 140, the piezoelectric layer 150, and the second electrode 160 may vibrate in a predetermined direction. The support member 134 may be provided on one side of the cavity 133.

The thickness of the support member 134 may be the same as the thickness of the cavity 133. Thus, the upper surfaces provided by the cavity 133 and the support member 134 may be substantially flat. According to an embodiment, the resonating unit 155 may be disposed on a planarized surface from which a step is removed, such that insertion loss and attenuation characteristics of the bulk acoustic resonator 100 may be improved.

A cross-section of the support member 134 may have a substantially trapezoidal shape. Specifically, the width of the upper surface of the support member 134 may be wider than the width of the lower surface of the support member 134, and a side surface connecting the upper surface and the lower surface may be inclined. The support member 134 may be formed of a material that is not etched in an etching process to remove the sacrificial layer. For example, the support member 134 may be formed of the same material as the insulating layer 115. For example, the support member 134 may be formed of silicon dioxide (SiO₂) or silicon nitride (Si₃N₄), or a combination of silicon dioxide (SiO₂) and silicon nitride (Si₃N₄).

According to an embodiment, the side surface of the support member 134 may be formed to be inclined to prevent an abrupt step from occurring at a boundary between the support member 134 and the sacrificial layer, and the width of the lower surface of the support member 134 may be formed to be narrow to prevent occurrence of a dishing phenomenon. For example, an angle between the lower surface and the side surface of the support member 134 may be 110° to 160°, and the width of the lower surface of the support member 134 may be 2 μm to 30 μm.

The auxiliary support member 135 may be provided outside (e.g., a lateral direction) of the support member 134. The auxiliary support member 135 may be formed of the same material as the support member 134. In addition, according to embodiments, the auxiliary support member 135 may be formed of a material different from that of the support member 134. For example, when the auxiliary support member 135 is formed of a material different from the material of the support member 134, the auxiliary support member 135 may correspond to one portion of the sacrificial layer formed on the insulating layer 115 which remains after the etching process.

As described above, the resonating unit 155 may include the first electrode 140, the piezoelectric layer 150, and the second electrode 160. A common region of the first electrode 140, the piezoelectric layer 150, and the second electrode 160 overlapping in a vertical direction may be located in an upper portion of the cavity 133. The first electrode 140 and the second electrode 160 may be formed of any one of gold (Au), titanium (Ti), tantalum (Ta), molybdenum (Mo), ruthenium (Ru), platinum (Pt), tungsten (W), aluminum (Al), iridium (Ir), and nickel (Ni), or an alloy thereof. The piezoelectric layer 150 is a layer causing a piezoelectric effect converting electrical energy into mechanical energy in the form of elastic waves. One of zinc oxide (ZnO), aluminum nitride (AlN), doped aluminum nitride, lead zirconate titanate, quartz, and the like may be selectively used in the piezoelectric layer 150. In an example in which the piezoelectric layer 150 is formed of doped aluminum nitride, the piezoelectric layer 150 may further include a rare earth transition metal, or an alkaline earth metal. For example, the rare earth metal may include any one or any combination of any two or more of scandium (Sc), erbium (Er), yttrium (Y), and lanthanum (La), and a rare earth content may be 1 to 20 at %. The transition metal may include any one or any combination of any two or more of hafnium (Hf), titanium (Ti), zirconium (Zr), tantalum (Ta), and niobium (Nb). In addition, the alkaline earth metal may also include magnesium (Mg).

The membrane 130 is formed of a material that is not easily removed in the process of forming the cavity 133. For example, when a halide-based etching gas such as fluorine (F), chlorine (Cl), or the like is used to remove some the sacrificial layer to form the cavity 133, the membrane 130 may be formed of a material having a low reactivity with the etching gas. In this case, the membrane 130 may include either one or both of silicon dioxide (SiO2) and silicon nitride (Si3N4). In addition, the membrane 130 may be formed of a dielectric layer containing any one or any combination of any two or more of magnesium oxide (MgO), zirconium oxide (ZrO2), aluminum nitride (AlN), lead zirconate titanate (PZT), gallium arsenide (GaAs), hafnium oxide (HfO2), aluminum oxide (Al2O3), titanium oxide (TiO2), and zinc oxide (ZnO), or may be formed of a metal layer containing any one or any combination of any two or more of aluminum (Al), nickel (Ni), chrome (Cr), platinum (Pt), gallium (Ga), and hafnium (Hf).

According to embodiments, a seed layer made of the aluminum nitride (AlN) may be formed on the membrane 130. For example, the seed layer may be disposed between the membrane 130 and the first electrode 140. The seed layer may be formed using a dielectric or metal having an HCP structure in addition to aluminum nitride (AlN). In an example in which the seed layer is formed of metal, the seed layer may be formed of titanium (Ti).

The protective layer 170 may be disposed on the second electrode 160 to prevent the second electrode 160 from being exposed externally. The protective layer 170 may be formed of any one of a silicon oxide-based insulating material, a silicon nitride-based insulating material, an aluminum nitride-based insulating material, and an aluminum oxide based insulating material. A metal layer 180 may be formed on the first electrode 140 and the second electrode 160, which are exposed externally.

The resonating unit 155 may include an active region and an inactive region. The active region of the resonating unit 155 is a region that vibrates and resonates in a predetermined direction by a piezoelectric phenomenon generated in the piezoelectric layer 150 when electrical energy such as a radio frequency signal is applied to the first electrode 140 and the second electrode 160. The active region of the resonating unit 155 may correspond to a region in which the first electrode 140, the piezoelectric layer 150, and the second electrode 160 are superimposed in a vertical direction in an upper portion of the air cavity 133. The inactive region of the resonating unit 155 is a region that is not resonated by the piezoelectric phenomenon even though the electrical energy is applied to the first electrode 140 and the second electrode 160, and may correspond to a region disposed externally of the active region.

The resonating unit 155 outputs a radio frequency signal having a specific frequency by using the piezoelectric phenomenon. Specifically, the resonating unit 155 may output the radio frequency signal having a resonance frequency corresponding to vibration according to the piezoelectric phenomenon of the piezoelectric layer 150.

A cap 200 may be bonded to a laminated structure forming a plurality of bulk acoustic resonators 100. The cap 200 may be formed in a cover shape having an internal space in which the plurality of bulk acoustic resonators 100 are accommodated. The cap 200 may be formed in a hexahedron shape having an open lower surface, and may include an upper portion and a plurality of side portions connected to the upper portion.

The cap 200 may be formed with an accommodating region in a center of the cap 200 to accommodate the resonating unit 155 of the plurality of bulk acoustic resonators 100. The laminated structure may be bonded to the plurality of side portions in a bonding region, and the bonding region of the laminated structure may correspond to an edge of the laminated structure. The cap 200 may be bonded to the substrate 110. In addition, the cap 200 may be bonded to any one or any combination of any two or more of the protective layer 170, the membrane 130, and the insulating layer 115, the first electrode 140, the piezoelectric layer 150, the second electrode 160, and the metal layer 180.

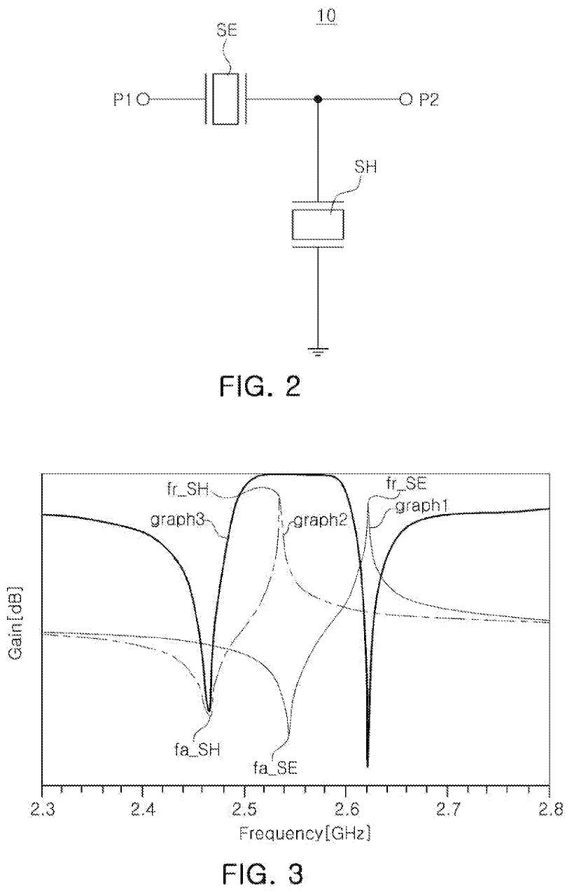

FIG. 2 is a circuit diagram of the filter 10, according to an embodiment. FIG. 3 shows a frequency response of the filter of FIG. 2.

Referring to FIG. 2, the filter 10 may include a series resonator (SE) disposed between a first port P1 and a second port P2 and a shunt resonator (SH) disposed between the series resonator (SE) and a ground. The series resonator (SE) and the shunt resonator (SH) may each correspond to the bulk acoustic resonator 100 illustrated in FIG. 1.

One series resonator (SE) and one shunt resonator (SH) are illustrated in FIG. 2, but according to embodiments, a plurality of series resonators (SE) may be disposed between the first port P1 and the second port P2 and a plurality of shunt resonators (SH) that are different from each other, may be disposed between each of the series resonators (SE) and the ground. In addition, it is illustrated in FIG. 2 that the filter 10 is configured as a ladder-type filter, including the series resonator (SE) and the shunt resonator (SH). However, according to embodiments, the filter 10 may be configured as a lattice-type filter.

Referring to FIG. 3, a first graph (Graph 1) represents a frequency response (Z, Impedance) of the series resonator (SE), a second graph(Graph 2) represents a frequency response (Z, Impedance) of the shunt resonator (SH), and a third graph (Graph 3) represents a frequency response (S-parameter) by the filter including the series resonator (SE) and the shunt resonator (SH).

The frequency response by the series resonator (SE) has a resonance frequency (fr_SE) and an anti-resonance frequency (fa_SE), and the frequency response by the shunt resonator (SH) has a resonance frequency (fr_SH) and an anti-resonance frequency (fa_SH).

Referring to the frequency response of the filter, a pass band and a band width of the filter may be determined by the anti-resonance frequency (fa_SE) of the series resonator (SE) and the resonance frequency (fr_SH) of the shunt resonator (SH).

5G communication is expected to connect more devices efficiently with a higher data capacity and a faster data transfer rate compared to the existing long term evolution (LTE) communication. As the width between adjacent frequency bands decreases in 5G communications, it is necessary to reduce interference between adjacent bands by using a BAW filter having excellent attenuation characteristics.

However, since a BAW filter having a bandpass characteristic has a narrow frequency interval between the resonance frequency and the anti-resonance frequency of about 200 MHz, the attenuation characteristic is excellent, but it is difficult to form the pass band wider than 600 MHZ. Thus, there is a problem in that it is difficult to apply the BAW filter to 5G communications, in which broadband frequency characteristics are required.

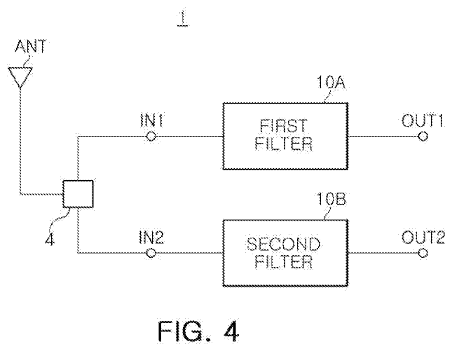

FIG. 4 is a block diagram of a front end module 1, according to an embodiment.

Referring to FIG. 4, the front end module may include a first filter 10A and a second filter 10B. The first filter 10A and the second filter 10B may be implemented by a single chip. The first filter 10A and the second filter 10B may be referred to as filter units.

The first filter 10A may be disposed between a first input terminal (IN1) and a first output terminal (OUT1), and the second filter 10B may be disposed between a second input terminal (IN2) and a second output terminal (OUT2).

The first input terminal (IN1) and the second input terminal (IN2) are commonly connected to an antenna (ANT). According to an embodiment, a diplexer 4 may be disposed between the antenna (ANT) and the first input terminal (IN1), and between the antenna (ANT) and the second input terminal (IN2).

The first output terminal (OUT1) and the second output terminal (OUT2) may each be connected to a signal processing element such as a power amplifier (PA), a low noise amplifier (LNA), or the like. For example, any one of the first output terminal (OUT1) and the second output terminal (OUT2) may be connected to both the PA and the LNA, and in this case, the PA may be disposed in a transmission path of the radio frequency signal, and the LNA may be disposed in a receiving path of the radio frequency signal.

The first filter 10A may operate as a bandpass filter. For example, the first filter 10A may operate as a bandpass filter having a lower limit frequency of 4.4 GHz and an upper limit frequency of 5.0 GHz. The first filter 10A may support cellular communications in the 4.4 GHz to 5.0 GHz band. According to an embodiment, the first filter 10A may support cellular communications in the 3.3 GHz to 4.2 GHz band.

The second filter 10B may operate as a high-pass filter. For example, the second filter 10B may operate as a high-pass filter having a lower limit frequency of 5.15 GHz. The second filter 10B may support Wi-Fi communications in the 5.15 GHz to 5.835 GHz band.

The first filter 10A and the second filter 10B may each include at least one bulk acoustic resonator. The first filter 10A and the second filter 10B constituted by bulk acoustic resonators may implement excellent attenuation characteristics. Therefore, despite a band gap, which is extremely narrow, of 5.0 GHz corresponding to the upper limit frequency of the first filter 10A and to the lower limit frequency of the second filter 10B, interference between the passband of the first filter 10A and the passband of the second filter 10B may be lowered.

In addition, the second filter 10B may be implemented as a high-pass filter, and may support Wi-Fi communications in a 5.15 GHz to 5.835 GHz band having a bandwidth exceeding 600 MHz.

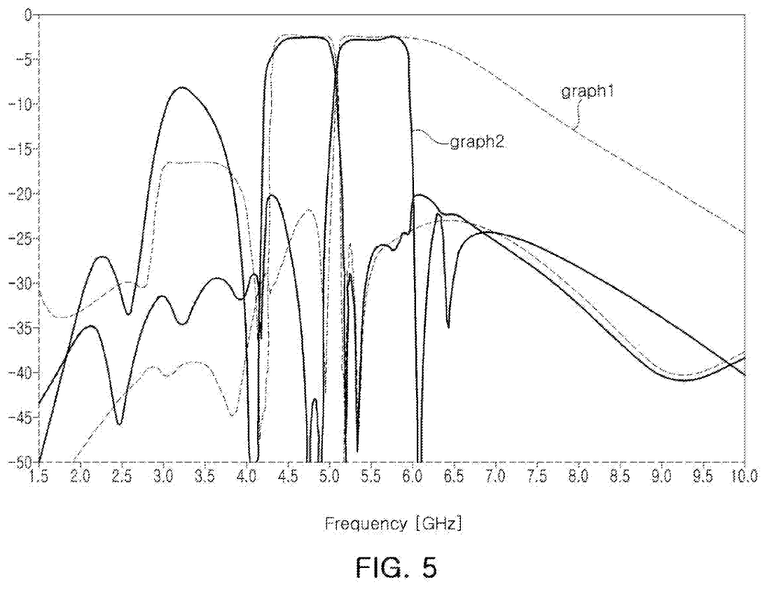

FIG. 5 is a simulation graph, according to an embodiment.

In FIG. 5, a first graph (graph 1) represents the frequency response of an embodiment according to the front end module 1 of FIG. 4, and a second graph (graph 2) represents the frequency response of a Comparative Example. The Comparative Example includes the first filter 10A of FIG. 4 and a band pass filter instead of the second filter 10B of FIG. 4.

Referring to the first and second graphs 1 and 2, it can be seen that insertion loss is improved by about 0.9 dB in the region of 5.15 GHz to 5.835 GHz or more in the embodiment of the present disclosure as compared to the Comparative Example. In addition, unlike Comparative Example, the disclosed embodiment exhibited that the band of 5.15 GHz or more may be completely covered, and a Wi-Fi band of 6 GHz, which is expected to be used later, may be also secured.

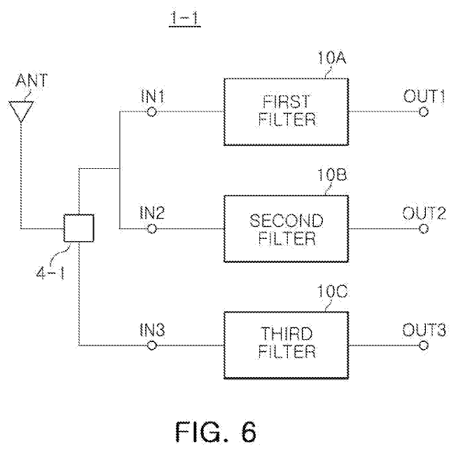

FIG. 6 is a block diagram of a front end module 1-1, according to another embodiment.

Since the front end module 1-1 is similar to the front end module 1 of FIG. 4, duplicate descriptions will be omitted and the following description will focus on differences between the front end module 1-1 and the front end module 1.

Referring to FIG. 6, the front end module 1-1 further includes, in comparison to the front end module 1 of FIG. 4, a third filter 10c in addition to the first filter 10A and the second filter 10B. The first filter 10A, the second filter 10B, and the third filter 10C may be implemented by a single chip. The first filter 10A, the second filter 10B, and the third filter 10C may be referred to as filter units.

The first filter 10A may be disposed between a first input terminal (IN1) and a first output terminal (OUT1), the second filter 10B may be disposed between a second input terminal (IN2) and a second output terminal (OUT2), and the third filter 10C may be disposed between a third input terminal (IN3) and a third output terminal (OUT3).

The first input terminal (IN1), the second input terminal (IN2), and the third input terminal (IN3) may be commonly connected to the antenna (ANT). According to an embodiment, a diplexer 4-1 may be disposed between the antenna (ANT) and the first input terminal (IN1), between the antenna (ANT) and the second input terminal (IN2), and between the antenna (ANT) and the third input terminal (IN3).

Each of the first output terminal (OUT1), the second output terminal (OUT2), and the third output terminal (OUT3) may be connected to a signal processing device such as a power amplifier (PA), a low noise amplifier (LNA), or the like. For example, one of the first output terminal (OUT1), the second output terminal (OUT2), and the third output terminal (OUT3) may be connected to both the PA and the LNA, and the PA may be connected to a transmission path of the radio frequency signal, and the LNA may be disposed in a receiving path of the radio frequency signal.

The first filter 10A may operate as a bandpass filter. For example, the first filter 10A may operate as a bandpass filter having a lower limit frequency of 4.4 GHz and an upper limit frequency of 5.0 GHz. The first filter 10A may support cellular communications in the 4.4 GHz to 5.0 GHz band.

The second filter 10B may operate as a high-pass filter. For example, the second filter 10B may operate as high-pass filter having a lower limit frequency of 5.15 GHz. The second filter 10B may support Wi-Fi communications in the 5.15 GHz to 5.835 GHz band.

The third filter 10C may operate as a bandpass filter. For example, the third filter 10C may operate as a bandpass filter including a lower limit frequency of 2.4 GHz and an upper limit frequency of 2.4835 GHz. The third filter 10C may support Wi-Fi communications in the 2.4 GHz to 2.4835 GHz band.

According to an embodiment, the second filter 10B constituted by a bulk acoustic resonator may be implemented as a high-pass filter, and may support a 5.15 GHz to 5.835 GHz band having a bandwidth exceeding 600 MHz.

As set forth above, according to a front end module disclosed herein, interference between designed channels may be reduced while covering a wide frequency band of next generation mobile communications.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A front end module, comprising:
a first filter connected to a first input terminal, and configured to operate as a bandpass filter supporting communications in a 4.4 GHz to 5.0 GHz band; and
a second filter connected to a second input terminal, and configured to operate as a high-pass filter supporting communications in a 5.15 GHz to 5.835 GHz band,
wherein the first input terminal and the second input terminal are connected to a common input terminal.

2. The front end module of claim 1, wherein the first filter and the second filter each comprise at least one bulk acoustic resonator.

3. The front end module of claim 1, wherein the first filter has a lower limit frequency of 4.4 GHz and an upper limit frequency of 5.0 GHz.

4. The front end module of claim 1, wherein the second filter has a lower limit frequency of 5.15 GHz.

5. The front end module of claim 4, wherein the second filter is configured to support a radio frequency signal of 5.15 GHz or more.

6. The front end module of claim 1, wherein the first filter is configured to support cellular communications.

7. The front end module of claim 1, wherein the second filter is configured to support Wi-Fi communications.

8. The front end module of claim 1, wherein the first filter and the second filter are implemented as a single chip.

9. A front end module, comprising:
an antenna;
a diplexer connected to the antenna; and
a filter unit comprising a first filter connected to the diplexer and configured to support communications in a 4.4 GHz to 5.0 GHz band, and a second filter connected to the diplexer and configured to support communications in a 5.15 GHz to 5.835 GHz band,
wherein the first filter is configured to operate as a bandpass filter and the second filter is configured to operate as a high-pass filter.

10. The front end module of claim 9, wherein the second filter has a lower limit frequency of 5.15 GHz.

11. The front end module of claim 10, wherein the second filter is configured to cover a radio frequency signal of 5.15 GHz or more.

12. The front end module of claim 9, wherein the filter unit further comprises a third filter connected to the diplexer and configured to support communications in a 2.4 GHz to 2.4835 GHz band.

13. The front end module of claim 12, wherein the first filter, the second filter, and the third filter each comprise at least one bulk acoustic resonator.

14. The front end module of claim 12, wherein the first filter, the second filter, and the third filter are implemented as a single chip.

15. The front end module of claim 12, wherein the second filter and the third filter are configured to support Wi-Fi communications.

16. The front end module of claim 9, wherein the first filter is configured to support cellular communications.
